(19) United States
(12) Patent Application Publication
(10) Pub. No.: US 2011/0228803 A1
(43) Pub. Date: Sep. 22, 2011

(54) VCSEL WITH INTEGRAL RESISTIVE REGION

(75) Inventors: James K. Guenter, Garland, TX (US); Gyoungwon Park, Allen, TX (US)

(73) Assignee: FINISAR CORPORATION, Sunnyvale, CA (US)

(21) Appl. No.: 12/727,822

(22) Filed: Mar. 19, 2010

(51) Int. Cl. H01S 3/10; H01S 5/026; H01S 5/183; G01N 21/59; H01L 21/265; H03B 17/00; H01L 33/46

(52) U.S. Cl. 372/38.07; 372/46.013; 372/46.01; 356/437; 331/94.1; 438/29; 257/E21.334; 257/E33.068

(57) ABSTRACT

In one embodiment, a VCSEL includes a plurality of semiconductor layers, an insulative region, a resistive region, and a remainder region. The semiconductor layers include a lower mirror, an active region, and an upper mirror. The active region is disposed over the lower mirror and includes a first lasing region. The upper mirror is disposed over the active region. The insulative region and the resistive region are integrally formed in the semiconductor layers. The remainder region includes the semiconductor layers except for the insulative region and the resistive region integrally formed in the semiconductor layers. The insulative region is disposed between the resistive region and the remainder region.

### BACKGROUND

1. Field of the Invention

Embodiments of the present invention generally relate to optical vertical cavity surface emitting lasers (“VCSELs”). In particular, some example embodiments relate to VCSELs that include a resistive region.

2. Related Technology

Vertical Cavity Surface Emitting Lasers, or VCSELs, are a type of semiconductor laser in which laser light is emitted perpendicular to the planer surface of the wafer on which the VCSEL is formed. VCSELs have many uses, including applications in telecommunications, data storage, barcode readers, gas sensing devices, welding, image scanning, and high-speed printing systems. Because VCSELs incorporate the mirrors monolithically in their design, they allow for on-wafer testing and the fabrication of one-dimensional or two-dimensional laser arrays. For some applications, VCSELs are favored because they emit a beam with a relatively small angular divergence, making efficient collection of the emitted beam easier.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY OF SOME EXAMPLE EMBODIMENTS

In general, example embodiments relate to a VCSEL including a resistive region that may perform one or more of several functions including impedance matching and heating the lasing region of the VCSEL.

In one example embodiment, a VCSEL includes a plurality of semiconductor layers, an insulative region, a resistive region, and a remainder region. The semiconductor layers include a lower mirror, an active region, and an upper mirror. The active region is disposed over the lower mirror and includes a first lasing region. The upper mirror is disposed over the active region. The insulative region and the resistive region are integrally formed in the semiconductor layers. The remainder region includes the semiconductor layers except for the insulative region and the resistive region integrally formed in the semiconductor layers. The insulative region is disposed between the resistive region and the remainder region.

In another example embodiment, an optoelectronic module includes a housing, a printed circuit board assembly (“PCBA”), a transmitter optical subassembly (“TOSA”), and a temperature sensor. The housing includes a top shell and a bottom shell. The PCBA is at least partially enclosed within the housing and includes control circuitry. The TOSA is electrically connected to the PCBA and includes a VCSEL. The VCSEL includes a plurality of semiconductor layers, an insulative region, a resistive region, and a remainder region. The semiconductor layers include a lower mirror, an active region, and an upper mirror. The active region is disposed over the lower mirror and includes a lasing region. The upper mirror is disposed over the active region. The insulative region and the resistive region are integrally formed in the semiconductor layers. The resistive region is disposed proximate the lasing region and is electrically connected to the control circuitry. The remainder region includes all of the semiconductor layers except for the insulative region and the resistive region integrally formed in the semiconductor layers. The insulative region is configured to substantially electrically isolate the resistive region from the remainder region.

In yet another example embodiment, an atomic clock includes control circuitry, a VCSEL, and a wavelength sensor. The VCSEL is electrically connected to the control circuitry and includes a plurality of semiconductor layers, an insulative region, a resistive region, and a remainder region. The semiconductor layers include a substrate, a lower mirror disposed over the substrate, an active region disposed over the lower mirror, the active region including a lasing region, and an upper mirror disposed over the active region. The insulative and resistive regions are integrally formed in the semiconductor layers. The resistive region is disposed proximate the lasing region and is electrically connected to the control circuitry. The remainder region includes all of the semiconductor layers except for the insulative and resistive regions. The insulative region is configured to substantially electrically isolate the resistive region from the remainder region. The wavelength sensor is electrically connected to the control circuitry and is configured to generate an electrical signal indicative of a wavelength of light emitted by the VCSEL to the control circuitry. The control circuitry is configured to adjust an amount of current provided to the resistive region of the VCSEL in response to the electrical signal.

In yet another example embodiment, a gas detection device includes a VCSEL, an optical detector, a gas chamber, and control circuitry. The VCSEL is configured to emit electromagnetic radiation having a central wavelength and includes a plurality of semiconductor layers, an insulative region, a resistive region, and a remainder region. The semiconductor layers include a substrate, a first mirror disposed over the substrate, an active region disposed over the first mirror, the active region including a lasing region, and a second mirror disposed over the active region. The insulative and resistive regions are integrally formed in the semiconductor layers. The resistive region is disposed proximate the lasing region. The remainder region includes all of the semiconductor layers except for the insulative and resistive regions. The insulative region is configured to substantially electrically isolate the resistive region from the remainder region. The optical detector is disposed in an optical path of the VCSEL. The gas chamber is disposed in the optical path of the VCSEL between the VCSEL and the optical detector. The control circuitry is electrically connected to the resistive region of the VCSEL and to the optical detector. The control circuitry is configured to vary the central wavelength of the electromagnetic radiation emitted by the VCSEL between a first wavelength and a second wavelength.

In yet another example embodiment, a method of creating a VCSEL includes forming a plurality of semiconductor layers including a substrate, a lower mirror and an active region. An upper mirror is formed over the plurality of semiconductor layers, the upper mirror including at least first and second layers. Forming the upper mirror includes depositing the first layer above the active region, and depositing the second layer over the first layer. The first layer has a lower surface and an upper surface including an oxidizable material. The second layer has an upper surface. An etched region is formed in the second layer, the etched region extending from the upper surface of the second layer to a depth that at least partially penetrates the upper surface of the first layer. The etched region is included in an insulative region configured to substantially electrically insulate a resistive region integrally formed in the upper mirror. At least the first and second layers are exposed to an oxidant, wherein the oxidant oxidizes at least a portion of the first layer to form an oxidized region in the first layer, the oxidized region being included in the insulative region and being disposed beneath the resistive region.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

These and other aspects of example embodiments will become more fully apparent from the following description and appended claims.

### BRIEF DESCRIPTION OF THE DRAWINGS

To further clarify various aspects of some embodiments of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a perspective view of a first example VCSEL;

FIG. 2 is a top view of the example VCSEL of FIG. 1;

FIG. 3a is a schematic view of a first example driver circuit that may be employed to drive the example VCSEL of FIG. 1;

FIG. 3b is a schematic view of a second example driver circuit that may be employed to drive the example VCSEL of FIG. 1;

FIGS. 4a-4e are cross sectional views of the example VCSEL of FIG. 1 after various manufacturing steps;

FIG. 5 is a flowchart of an example method of manufacturing the example VCSEL of FIG. 1;

FIGS. 6a and 6b are a top view and a perspective view of a second example

FIG. 7 is a top view of a third example VCSEL;

FIG. 8 is an exploded perspective view of an example optoelectronic module in which the example VCSELs of FIGS. 1 and 6a-7 can be implemented;

FIG. 9 is a schematic view of an example gas sensing detector in which the example VCSELs of FIGS. 1 and 6a-7 can be implemented;

FIG. 10 is a schematic view of an example atomic clock in which the example VCSELs of FIGS. 1 and 6a-7 can be implemented;

FIG. 11 is a schematic view of an example control circuit in which the example VCSELs of FIGS. 1 and 6a-7 can be implemented;

FIG. 12a illustrates an example resistive region that can be implemented in the VCSEL of FIGS. 6a-6b;

FIG. 12b illustrates a single wrap resistive region according to some embodiments; and

FIG. 12c illustrates a split wrap resistive region according to some embodiments.

### DETAILED DESCRIPTION

The following description describes one or more examples of processes, machines, manufactures, or compositions of matter. As examples, they are not limiting. The disclosure also includes figures or drawings which are diagrammatic and schematic representations of various examples and are also not limiting.

Unless context or logic suggests otherwise, the following definitions apply throughout this application. “Region” refers to a three-dimensional volume. A region may or may not be contiguous. “Area” refers to part or all of a surface and may or may not be contiguous. “VCSEL” is an acronym referring to a Vertical Cavity Surface Emitting Laser. A VCSEL may include one or more lasing regions. “Light” refers to any electromagnetic radiation, whether visible to the human eye or not. Terms related to direction, e.g., “upper”, “lower”, “above”, “below”, “lateral”, etc, describe the relative position of various features within a particular example, and hence are not limiting. The words “include”, “have”, and “comprise” are used synonymously and in an open-ended manner. A “subset” of a “set” may include one or more of that which is in the “set”. A subset may include all that which is in the set. A “layer” may include one or more “layers”. A “step” is any portion of a process or method, including possibly the entire process or method. A “step” may include multiple steps therein. The terms “insulating”, “insulative”, “conductive”, and “resistive” refer to electrical properties, as opposed to heat transfer properties. The term “may” generally refers to an optional feature, property, structure, etc. Unless otherwise noted, none of the figures are necessarily to scale.

Where multiple examples are given, the disclosure herein may avoid redundant description for reasons of brevity and clarity. It is assumed that the reader may draw appropriate inferences where context and reason demand.

Reference will now be made to the drawings wherein like structures will be provided with like reference designations. It should be understood that the drawings are diagrammatic and schematic representations of exemplary embodiments and, accordingly, are not limiting of the scope of the present invention, nor are the drawings necessarily drawn to scale.

### I. First Example VCSEL

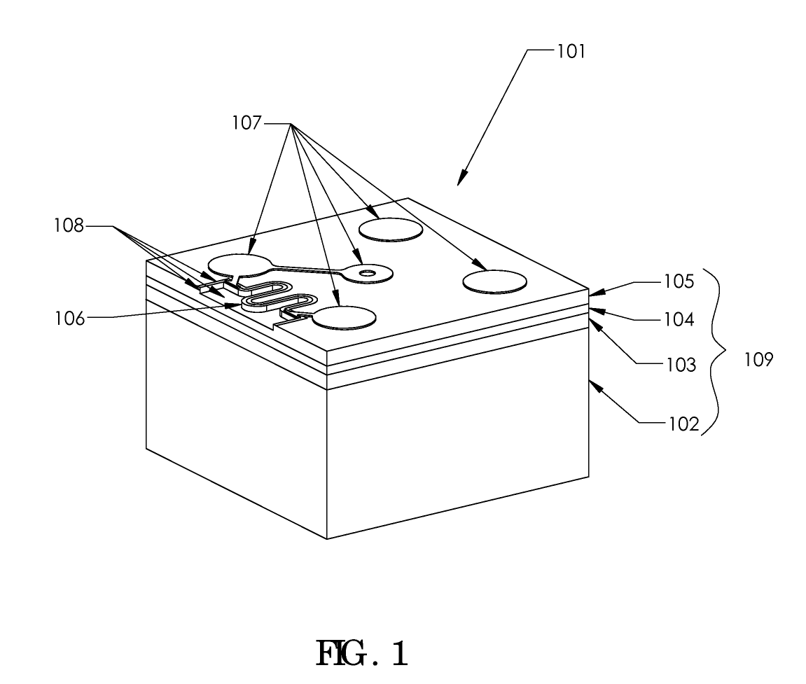

Reference is first made to FIG. 1, which is a perspective view of a first example VCSEL 101 including a resistive region configured to impedance match the VCSEL 101 to a particular drive circuit according to some embodiments. In the illustrated example, the VCSEL 101 includes a substrate 102, lower mirror 103, active region 104, upper mirror 105, resistive region 106, conductive region 107 and insulative region 108. The foregoing layers and structures of VCSEL 101 collectively form semiconductor body 109. The semiconductor body 109 further includes a remainder region including the portions of VCSEL 101 which are not included in the resistive region 106 and the insulative region 108.

The remainder region, resistive region 106 and/or the insulative region 108 may be disposed in intimate contact with each other and/or with other regions spaced between. In some cases, one or more of the remainder region, resistive region 106 or insulative region 108 include layers formed through a semiconductor growth process such as, for example, epitaxial deposition.

Substrate 102 is configured to provide structural support for the regions that lie thereon in some embodiments. Substrate 102 may be homogenous or may include several regions of different material. In the example of FIG. 1, substrate 102 is the bottommost region. In other examples, other regions lie below substrate 102. Substrate 102 is made of an appropriate semiconductor material, such as, for example, Gallium Arsenide (“GaAs”).

Lower mirror 103 is disposed over substrate 102. Lower mirror 103 is generally configured to reflect light upwards, thereby contributing to the stimulated emission of light. Lower mirror 103 is a distributed Bragg reflector or any other suitable type of mirror. Lower mirror 103 is made of an appropriate semiconductor material, such as, for example, Aluminum Gallium Arsenide (“AlGaAs”).

The active region 104 is disposed over the lower mirror 103. Active region 104 includes a lasing region and a nonlasing region in some embodiments. The lasing region is a region of active region 104 that, by virtue of its position with respect to current providing elements or other design structures, is subjected to a lasing current during operation of the VCSEL 101. Active region 104 is additionally disposed beneath upper mirror 105. The nonlasing region of active region 104 is substantially uninvolved in the production of stimulated light emission in some embodiments. Active region 104 may be configured as a layer that spans the entire plan area of the semiconductor body 109 or may be configured in any other suitable shape. Active region 104 is made of an appropriate semiconductor material, such as, for example, AlGaAs.

Upper mirror 105 is disposed over the active region 104 and is generally configured to reflect light downwards. Upper mirror 105 is a distributed Bragg reflector or any other suitable type of mirror. Upper mirror 105 is made of AlGaAs or any other suitable material. Upper mirror 105 may be configured as a layer that covers the entire plan area of the VCSEL 101, as a region that overlies only a portion of the plan area of the VCSEL 101, or any other suitable shape.

The various semiconductor layers 102-105 of VCSEL 101 are described by way of example only and should not be construed to limit the invention. In some embodiments, for instance, the VCSEL 101 may include more layers than are disclosed with respect to FIG. 1 that may be disposed between or on any one or more of the layers 102, 103, 104, 105 of VCSEL 101. For example, although not illustrated in FIG. 1, an antireflective (“AR”) or a reflective coating can be disposed over the upper mirror 105.

In some embodiments, the resistive region 106 and insulative region 108 are integrally formed in one or more of the semiconductor layers 102-105 of VCSEL 101. In the illustrated example of FIG. 1, for instance, the resistive region 106 and insulative region 108 are integrally formed in the upper mirror 105. Resistive region 106 is substantially insulated from the remainder region of semiconductor body 109 by insulative region 108. In some embodiments, the insulative region 108 includes one or more etched regions, oxidized regions, and/or ion implant regions.

Conductive region 107 is substantially conductive and is made of gold, another suitable conductive metal, a combination of metals, or another conductive material. Conductive region 107 is configured to allow attachment of power sources and provide current to the lasing region of active region 104.

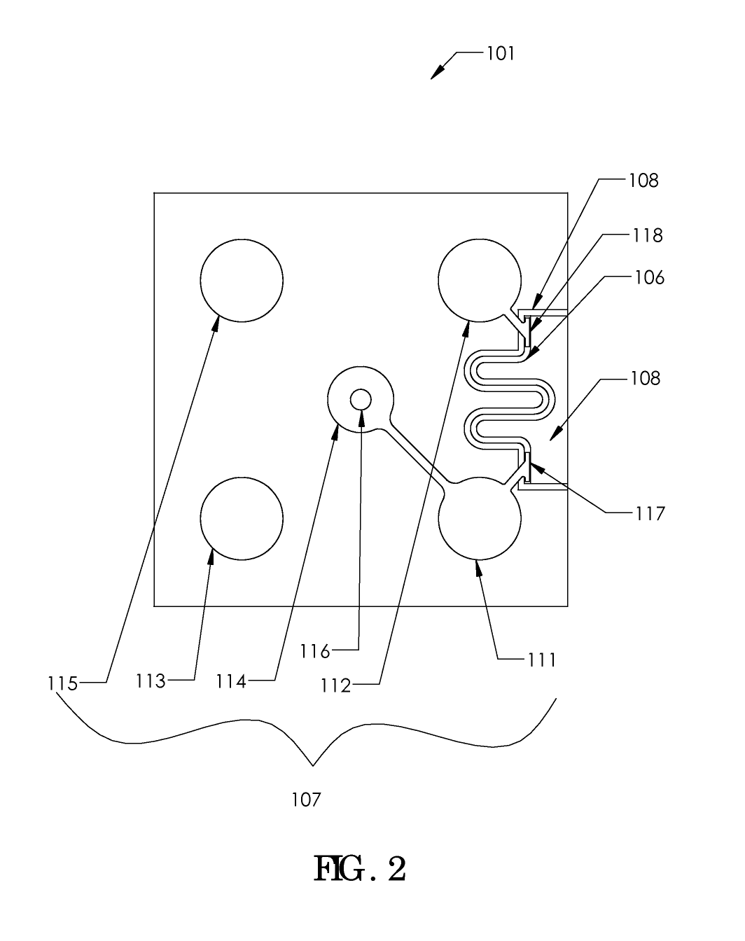

FIG. 2 is a top view of VCSEL 101 and discloses some details of at least portions of conductive region 107, insulative region 108, and the remainder region. Conductive region 107 includes a first top-side lasing contact 111, a second top-side lasing contact 112, a bottom-side lasing contact 113, a top-side lasing connect 114, and bottom-side lasing contact 115.

Top-side lasing connect 114 is generally disposed over the lasing region of active region 104 and is configured to deliver current to or accept current from the lasing region of active region 104, thereby contributing to the stimulated emission of light. In some embodiments, top-side lasing connect 114 includes a light emission opening 116, configured to allow light to escape from the lasing region of active region 104. Top-side lasing connect 114 is electrically coupled to first top-side lasing contact 111 in the illustrated embodiment. Top-side lasing connect 114 operates as an anode in some examples.

First top-side lasing contact 111 is connected to top-side lasing connect 114. First top-side lasing contact 111 may be substantially round or any other suitable shape. First top-side lasing contact 111 is configured to electrically connect to an outside driver by, for example, a wire or other conductor. Additionally, first top-side lasing contact 111 may be electrically connected to resistive region 106 via resistor connection pad 117.

Second top-side lasing contact 112 is electrically connected to resistive region 106. Second top-side lasing contact 112 is connected to the resistive region 106 via resistor connection pad 118. As illustrated in FIG. 2, second top-side lasing contact 112 is connected to one side of resistive region 106 while first top-side lasing contact 111 is connected to the opposite side of resistive region 106.

Bottom-side lasing contact 113 is configured to deliver current to or accept current from the lasing region of active region 104. Bottom-side lasing contact 113 may be electrically connected to a bottom-side lasing connect (not shown). The bottom-side lasing contact 113 may be disposed at any suitable position of the VCSEL 101 including, for instance, on the top side of VCSEL 101 or the bottom side of VCSEL 101. In some cases, the bottom-side lasing contact 113 operates as a cathode connection to VCSEL 101. The bottom-side lasing connect to which the bottom-side lasing contact 113 is connected is located substantially beneath top-side lasing connect 114 in some examples.

Features of VCSEL 101 allow a designer to better match the impedances between a driver circuit and VCSEL 101 in some embodiments. Impedance matching is generally an effort to match or nearly match the output impedance of a signal source to the input impedance of a load. Impedance matching may increase the percentage of power transferred between the signal source and the load and decrease signal reflections. As such, impedance matching may improve the operability of a laser such as a VCSEL in applications including optoelectronic modules used in optical telecommunication and/or data networks.

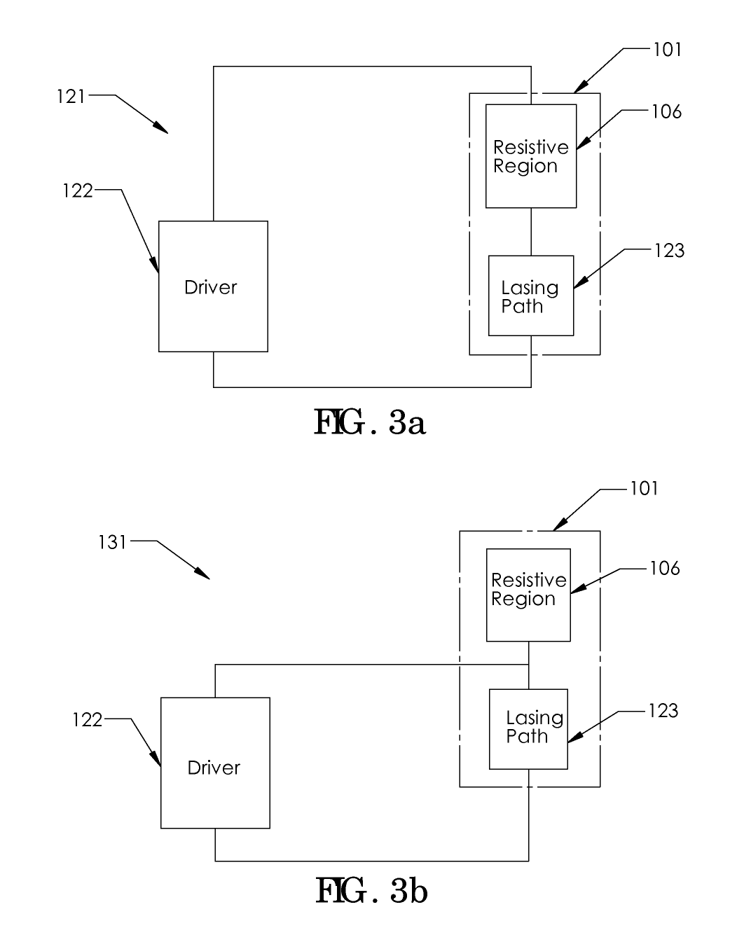

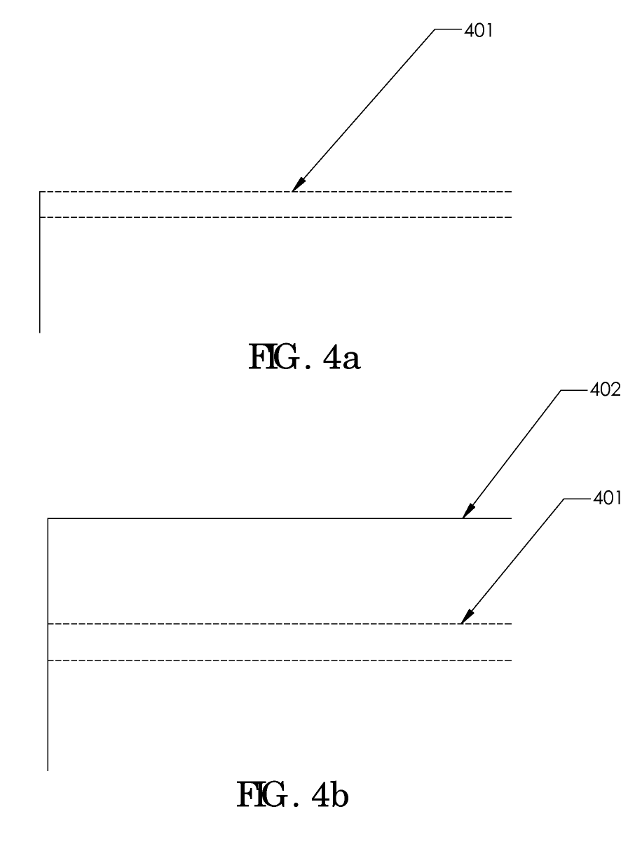

FIGS. 3a and 3b disclose two example operating modes for VCSEL 101. FIG. 3a illustrates a circuit configuration 121 which may operate in an impedance-matching mode. Circuit configuration 121 includes a driver 122 and VCSEL 101, the VCSEL 101 including a lasing path 123, and resistive region 106. In the impedance-matched mode, the lasing circuit 121 includes driver 122, resistive region 106, and lasing path 123. Lasing path 123 includes first top-side lasing contact 111, top-side lasing connect 114, a lasing region, a bottom-side lasing connect, and bottom-side lasing contact 113. Thus, the impedance-matching mode shown in FIG. 3a places resistive region 106 in series with lasing path 123. Placing resistive region 106 in series with lasing path 123 increases the output resistance presented to driver 122. In some embodiments, the resistive region 106 and the lasing path 123, including the lasing region of VCSEL 101, collectively present a predetermined input impedance to the driver 122.

Driver 122 is located outside of VCSEL 101 in some examples. For instance, driver 122 may be located on a separate circuit board. The driver 122 is configured to drive VCSEL 101 by providing electrical power, possibly in the form of current. One physical configuration that may produce the impedance-matching circuit configuration of FIG. 3a is a conduction line from driver 122 to second top-side lasing contact 112 and a conduction line from driver 122 to bottom-side lasing contact 113.

FIG. 3b depicts a circuit configuration 131 which may operate in a non-impedance-matching mode. Circuit configuration 131 includes substantially similar elements as circuit configuration 121. Specifically, circuit configuration 131 includes driver 122 and VCSEL 101, the VCSEL 101 including lasing path 123 and resistive region 106. In contrast to the circuit configuration 121 of FIG. 3A, circuit configuration 131 is configured such that resistive region 106 is substantially excluded from the lasing circuit. In some cases, substantially no or little current passes through resistive region 106 when driver 122 drives lasing path 123 in the circuit configuration 131 of FIG. 3b. One possible way to obtain circuit configuration 131 is to connect a conduction line from driver 122 to first top-side lasing contact 111 and to connect a conduction line from driver 122 to bottom-side lasing contact 113.

Thus, operating in circuit configuration 121 may cause VCSEL 101 to present a substantially different resistance value to driver 122 than operating in circuit configuration 131. Specifically, when configured as shown in FIG. 3a, circuit configuration 121 presents a resistance approximately equal to the sum of the resistance of the resistive region 106 and the resistance of the lasing path 123. This configuration may be useful where the output resistance of the driver 122 is substantially greater than the resistance of lasing path 123. Thus, resistive region 106, when employed in circuit configuration 121, at least partially impedance matches driver 122 to VCSEL 101.

Although much of the foregoing discussion has focused on the resistive aspects of the foregoing configuration, resistive region 106 may be replaced or augmented by capacitive or inductive elements that may further improve the match between the impedance of driver 122 and the impedance of VCSEL 101.

Optionally, VCSEL 101 may be configured such that resistive region 106 is electrically connected to the bottom-side lasing contact 113. As another option, a first resistive region may be electrically connected to top-side lasing connect 114 and a second resistive region may be electrically connected to the bottom-side lasing connect (not shown). Finally, resistive region 106 may be placed in parallel with lasing path 121, thereby reducing the resistance that VCSEL 101 presents to driver 122. This configuration may be useful where a designer seeks to match impedances where the impedance of the lasing path 123 is relatively high and/or the impedance of driver 122 is relatively low.

In some embodiments, VCSEL 101 is configured with the resistive region 106 distant from the lasing region corresponding to top-side lasing connect 114, thus possibly limiting the heat transferred from resistive region 106 to the lasing region corresponding to top-side lasing connect 114. For instance, VCSEL 101 may be configured with the resistive region 106 disposed no less than one quarter of the major lateral dimension of VCSEL 101 from the lasing region corresponding to top-side lasing connect 114.

Alternately, VCSEL 101 may be configured with resistive region 106 disposed relatively close to the lasing region corresponding to top-side lasing connect 114. Such a configuration may be useful when, for example, a designer wishes to ensure that some of the heat generated during operation by resistive region 106 is transferred to the lasing region corresponding to top-side lasing connect 114.

### II. Example Manufacturing Process

The foregoing section described some of the features and uses of VCSEL 101. This section discloses some of the specific structures and processes which may be included in or used to produce VCSEL 101. Much of the description in this section may also apply to further examples presented herein.

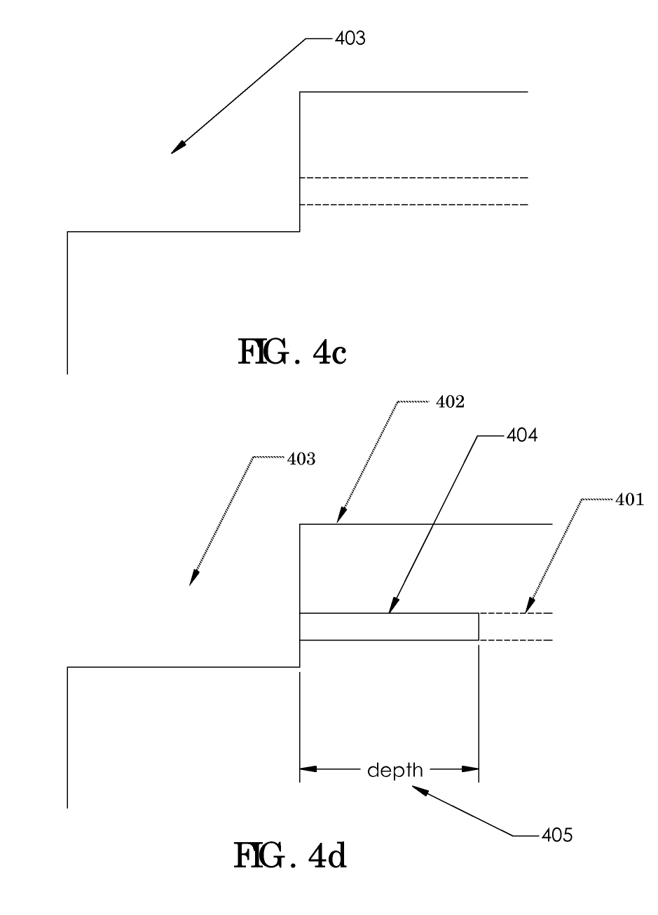

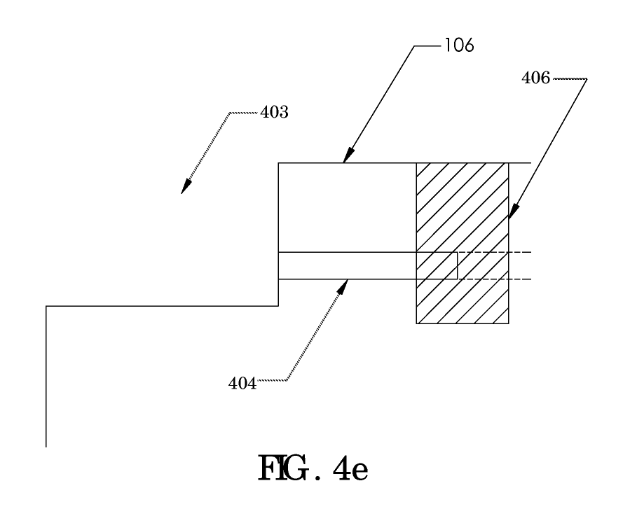

FIGS. 4a through 4e disclose cross sections of VCSEL 101 at various points within a possible process for producing VCSEL 101. FIG. 5 is a flow chart of an example method 506 for producing the VCSEL 101. In some embodiments, the VCSEL 101 is produced using one or more semiconductor deposition techniques. For example, the various layers of VCSEL 101 may be generated using epitaxial deposition. Through epitaxial deposition, layers of various ratios of different elements may be deposited. In some cases, a mixture of Aluminum, Gallium, and Arsenic, known as AlGaAs (Aluminum Gallium Arsenide) is deposited. In these cases, a layer with a greater percentage of aluminum may be more susceptible to oxidation by an oxidant.

FIG. 4a is a cross-sectional side view of a portion of VCSEL 101 after deposition of layer 401, shown in step 501 of FIG. 5. Layer 401 may be configured with a particular chemical makeup that renders it more susceptible to oxidation than at least some of the other layers within VCSEL 101. Thus, layer 401 is an example of an oxidizable layer. For instance, layer 401 may be configured to include more aluminum than other layers within VCSEL 101, thereby rendering layer 401 more susceptible to oxidation. Layer 401 may lie anywhere within the semiconductor structure of VCSEL 101 including, for instance, within substrate 102, lower mirror 103, active region 104, and/or upper mirror 105. As one example, layer 401 may lie within upper mirror 105. In some examples, upper mirror 105 includes a set of twenty-five reflective periods and oxidant susceptible layer 401 may lie within the first, second, third, or fourth layer from the bottom of upper mirror 105.

FIG. 4b is a cross-section of VCSEL 101 after deposition of layer 402. Layer 402 is deposited over the top of layer 401 and is less susceptible to oxidation than layer 401. For instance, layer 402 may include a lower percentage of aluminum than layer 401, rendering layer 402 less susceptible to oxidation. The relative susceptibility to oxidation of layer 401 as compared to layer 402 may be with reference to a particular oxidant or oxidizing environment used in an oxidation step discussed below. Layer 402 may lie anywhere within the semiconductor structure of VCSEL 101 above layer 401.

FIG. 4c is a cross-sectional side view of a portion of VCSEL 101 after VCSEL 101 is subjected to a step 503 of removing material which selectively removes material from the semiconductor body of VCSEL 101. The material removal step 503 includes, for instance, an etching process in which a portion of the semiconductor body 109 of VCSEL 101 is etched, using, for example, photolithography. Accordingly, the region of the VCSEL 101 from which material is removed during step 503 is referred to herein as “etched region 403.”

The material removal step 503 proceeds to a depth that includes some of layer 401. In some cases, the removal step 503 removes material clear through layer 401 and into the material beneath layer 401. The final configuration of VCSEL 101 leaves this volume, e.g., the etched region 403, unfilled (or filled with ambient air), or, fills the etched region 403 with another insulative material. The material removal step 503 may render the space initially occupied by the removed material substantially insulative or semi-insulative. Thus, etched region 403 forms a portion of the insulative region 108, and is an insulative lateral region. Additionally, the step 503 of removing material from the VCSEL 101 exposes portions of layer 401 in some embodiments, allowing subsequent oxidation thereof.

FIG. 4d is a cross-sectional side view of a portion of VCSEL 101 after an oxidation step 504. Oxidation step 504 includes oxidizing a portion 404 of layer 401 by an oxidant. The portion 404 is hereinafter referred to as “oxidized region 404.” One possible implementation of oxidation step 504 is the exposure of VCSEL 101 to an oxidizing environment consistent with certain parameters, such as steam at 400 degrees C. for a specified time. In some cases, a relatively greater amount of time in the oxidizing environment increases a depth 405 to which the oxidized region 404 laterally extends. The oxidation of layer 401 to create oxidized region 404 results in some embodiments in an oxidized region 404 that is insulating or semi-electrically insulating. Thus, oxidized region 404 forms a portion of the insulative region 108, and is an insulating base that is disposed beneath resistive region 106. In some examples, the thickness of the insulating base, e.g., of oxidized region 404, may be augmented by a buried ion implant (not shown). Alternatively, the insulating base may be formed by a buried ion implant alone, without the oxidation step.

FIG. 4e is a cross-sectional side view of a portion of VCSEL 101 after an ion implant step 505 in which ions are bombarded on to an area of the VCSEL 101 to create an ion implant region 406. The ions are protons or any other suitable type of ions such as, for example, oxygen ions, and are bombarded on to the area of the VCSEL 101 from above. In some embodiments, the ion implant region 406 extends from the top surface of the VCSEL 101 at least to the top surface of layer 401 and possibly through the bottom surface of layer 401. The ion implant region 406 is insulating or semi-insulating in some embodiments. The ion implant region 406 forms a portion of the insulative region 108, and is an insulative lateral region. It is understood that the lateral extent of ion implant region 406 across VCSEL 101 can be greater or less than that illustrated in FIG. 4e.

Accordingly, the method 506 results in the formation of a plurality of electrically insulative regions, including etched region 403, oxidized region 404, and ion implant region 406, which collectively form the insulative region 108 of VCSEL 101. The insulative region 108 substantially electrically isolates resistive region 106 from the remainder region of the VCSEL 101. The electrical isolation of resistive region 106 from the remainder region of VCSEL 101 substantially prevents current passing from resistive region 106 to the remainder region of VCSEL 101 and disrupting the operation of the lasing region or vice versa.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

Accordingly, in some cases, not every step listed in the method 506 of FIG. 5 is needed to substantially electrically isolate resistive region 106 from the remainder region of the VCSEL 101 semiconductor body 109. In some cases, for instance, the resistive region 106 can be electrically isolated using material removal step 502 and oxidization step 504 without performing ion implantation step 505. Alternately, the resistive region 106 can be electrically isolated using ion implantation step 505 without performing material removal 502 and/or oxidization step 504. Finally, perfect electrical isolation of the resistive region 106 from the remainder region of VCSEL 101 is not required.

In some cases, the resistive region 106 and insulative region 108 formed by process 506 are created without adding additional steps to some VCSEL manufacturing processes. Each step of the method 506 may also define a feature or features in the VCSEL 101 with functionality not directly related to the resistance functionality. For example, the deposition of layer 401 at step 501 forms a portion of the upper mirror 105 of the VCSEL 101 in some embodiments. Alternately or additionally, deposition of layer 402 at step 502 forms a portion of the upper mirror 105 of the VCSEL 101. Removal of material from the VCSEL 101 at step 503 may also contribute to the formation of a portion of an optical aperture of the VCSEL 101. Oxidizing step 504 alternately or additionally contributes to the formation of the optical aperture of the VCSEL 101. Finally, the ion implanting step 505 may optionally serve to electrically isolate VCSEL 101 from other VCSELs located on the same wafer during the manufacturing process. Such electrical isolation of the individual VCSELs on the wafer allows the VCSELs to be tested before the wafer is sectioned.

### III. Second Example VCSEL

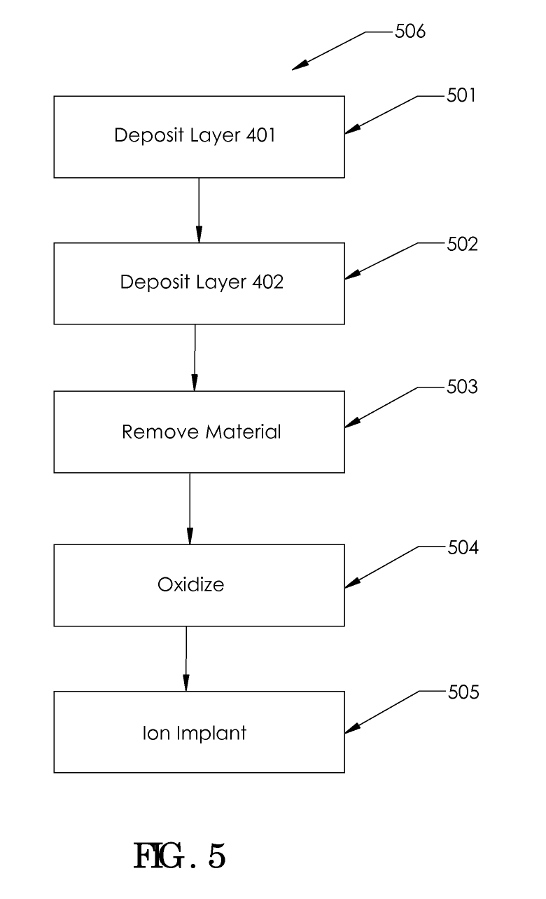

Reference is now made to FIG. 6a, which is a top view of another example VCSEL 601. FIG. 6b is a perspective detail view of the VCSEL 601. VCSEL 601 is configured to enable a driving circuit to heat a lasing region. VCSEL 601 includes a semiconductor body 602. The semiconductor body 602 is generally similar to the semiconductor body 109 of VCSEL 101 and includes, for instance, a substrate, a lower mirror, an active region, and an upper mirror. Semiconductor body 602 also includes a resistive region 603, an insulative region 604, and a remainder region 605. The resistive region 603 and insulative region 604 are integrally formed in one or more of the semiconductor layers (not labeled) of VCSEL 601, analogously as explained above with respect to VCSEL 101.

VCSEL 601 further includes a conductive region 610. Conductive region 610 includes a top-side lasing contact 611, a top-side lasing connect 612, a bottom-side lasing contact 613, a bottom-side lasing connect (not shown), and resistor contacts 614 and 615. Top-side lasing contact 611 is electrically connected to top-side lasing connect 612 and acts as an anode to VCSEL 601 in some embodiments. Bottom-side lasing contact 613 is electrically connected to bottom-side lasing connect and acts as a cathode to VCSEL 601 in some embodiments. When a driver circuit drives current through a lasing region located between the bottom-side lasing connect and top-side lasing connect 612, VCSEL 601 emits light by stimulated and spontaneous emission.

Resistor contact 614 is electrically connected to one end of resistive region 603 and resistor contact 615 is electrically connected to another end of resistive region 603. Resistive region 603 is located in close proximity to the lasing region, which lasing region is generally located under top-side lasing connect 612 in FIG. 6a. In the illustrated embodiment, resistive region 603 is configured in a double-wrap configuration in which current enters from resistor contact 615, travels first counter clockwise, then clockwise, then counter clockwise to resistor contact 614. Resistive region 603 is disposed sufficiently close to the lasing region to substantially heat the lasing region when a nondestructive heating current is passed through resistive region 603. For example, the nondestructive heating current may be less than five times a typical operating current of the lasing region. In some embodiments, VCSEL 601 allows control of the current passing through the resistive region 603 independent of the control of the current passing through the lasing region.

Although many different arrangements of etched regions, oxidized regions, and/or ion implant regions can be implemented to form an insulative region 604 between resistive region 603 and a remainder region of the VCSEL 601, FIG. 6b discloses one possible arrangement. In the illustrated embodiment, the insulative region 604 includes etched regions 616, exterior ion implant region 617a and interior ion implant regions 617b. Although not shown, the insulative region 604 may further include an oxidized region disposed beneath the resistive region 603. As shown, exterior ion implant region 617a encompasses the outer perimeter of the resistive region 603. In this and some other embodiments, the connections from the resistor contacts 614, 615 do not cross any etched regions 616.

The inner portion of insulative region 604 includes an alternating set of etched regions 616 and interior ion implant regions 617b. In the particular configuration shown in FIG. 6b, the etched regions 616 are substantially longer than the interior ion implant regions 617b, ensuring that an oxidant can penetrate far enough laterally beneath the resistive region 603 to create an oxidized insulating base.

A designer may configure resistive region 603 with a width and length according to the design requirements of VCSEL 601. One or more factors may be considered when configuring the size and shape of resistive region 603. In some embodiments, for instance, a maximum amount of heat to be produced by resistive region 603 is first determined. Once this value is determined, the voltage and/or current limitations of the driver circuit are considered. The foregoing values are then used to identify a particular resistance value and maximum operating current for resistive region 603. Using the determined resistance value, one or more length, width, and/or height combinations for resistive region 603 can be determined.

In some cases, two considerations may then inform the choice of which length/width/height combination to select for the resistive region 603. First, the accuracy of the processes from which resistive region 603 is formed may affect the resistance of resistive region 603. For instance, where the etched regions 616 of insulative region 604 are formed through an etching process, tolerances may cause variation in, for instance, the width of resistive region 603. Where resistive region 603 is specified as very narrow, these tolerance variations may cause significant variation in the resistance value of resistive region 603. Second, where the resistive region 603 has a low volume, the maximum operating current may cause the resistive region 603 to overheat, possibly causing the VCSEL 601 to fail. To avoid these possible issues, the double wrap configuration depicted in FIGS. 6a-6b may be beneficial in that it results in a relatively long effective length for the resistive region 603.

The VCSEL 601 of FIGS. 6a-6b having resistive region 603 with the double wrap configuration can be formed using the method 506 of FIG. 5 or another suitable method. In some cases, the resistive region 603 is formed in the VCSEL 601 without adding any additional steps to a standard VCSEL manufacturing process. Or, each step of the method 506, when practiced with respect to VCSEL 601, may form structures with functions substantially unrelated to the resistance functionality.

VCSELs, such as the VCSELs 101 and 601 described herein, can be used in numerous applications including optical telecommunication networks and optical data networks. An example configuration of an optical network includes a light emission device, such as a VCSEL, a light carrying device, such as an optical fiber, and a light receiving device, such as a photo sensitive diode. Such an optical network may transfer data by modulating the emitted light from the VCSEL between a relatively low power level and a relatively high power level.

Human eyes may be damaged by laser light with intensity and/or power above a certain safety threshold. Thus, regulations and/or good design practice may mandate an upper limit to the intensity and/or power of light emitted from a VCSEL used in optical networks, thus possibly setting an upper limit for the higher power level in an optical modulation format.

VCSELs generally produce light by two physical phenomena—spontaneous emission and stimulated emission. When a current below a lasing threshold is passed through a VCSEL, the VCSEL emits light primarily by spontaneous emission. When a current above the lasing threshold is passed through the VCSEL, the VCSEL emits light via both spontaneous emission and stimulated emission. Some optical networks rely partially or wholly on stimulated emission and treat the spontaneous emission as noise. For reasons related to the speed at which the light signal can be modulated, good design practice may require setting the lower power level of the optical modulation format substantially above that produced at the lasing threshold current.

In some cases, it may be desirable to have the components of an optical network operable over a wide range of temperatures so that, for instance, the optical network may operate in cold weather conditions. Some VCSELs produce more light power per unit of current at low temperatures than at high temperatures. As a result, in cold operating conditions, the upper limit for the high power level current may approach the low power level current, causing an increase in noise in the optical network. To counteract this affect, an optical network can incorporate VCSELs 601 with resistive region 603 that can be used to heat the VCSEL 601. Specifically, current can be passed through resistive region 603 when the ambient temperature is relatively low, thereby raising the temperature of the VCSEL 601 to maintain a relatively large separation between the high power level current and the lower power level current even at relatively lower ambient temperatures in some embodiments. The operating temperature range of the VCSEL 601 may thereby be greater and extend at least into lower temperature ranges than some VCSELs that lack a resistive region 603.

Additionally, the lasing region of VCSEL 601 may exhibit different lasing threshold currents as a function of temperature. A lower lasing threshold may improve the speed performance, noise performance, and/or relaxation oscillation performance of VCSEL 601. In some embodiments, the lasing threshold current of VCSEL 601 includes a minimum at some point within the operating temperature range and may rise at temperatures to either side of the minimum threshold current temperature point. A designer may adjust the minimum threshold current temperature point by incorporating various structures or design elements into a VCSEL. By raising the temperature at which VCSEL 601 operates when the ambient temperature is relatively low, resistive region 603 allows VCSEL 601 to be configured with a greater minimum threshold current temperature. As a result, VCSEL 601 can be operated in a narrow effective temperature range, thus reducing the variation in threshold current and improving the efficiency and reducing the noise in the light signal emitted from VCSEL 601 at both relatively high ambient temperatures and relatively low ambient temperatures.

Furthermore, the lasing region of a VCSEL emits light having a relatively longer wavelength when the lasing region of the VCSEL is relatively hot than when it is relatively cool. The resistive region 603 of VCSEL 601 allows some control of the wavelength of VCSEL 601 in some embodiments through control of the temperature of the VCSEL 601 via resistive region 603. Moreover, resistive region 603 may allow such control at least partially or completely independent of control of laser power. Independent control of the wavelength/temperature and laser power in VCSEL 601 may be useful in applications that require, for instance, emission of a specific wavelength or a wavelength sweep.

Finally, resistive region 603 may improve the response time, e.g., the rate at which the VCSEL 601 effective temperature may be tuned, of the VCSEL 601 due to the proximity of the resistive region 603 to the lasing region of VCSEL 601.

### IV. Third Example VCSEL

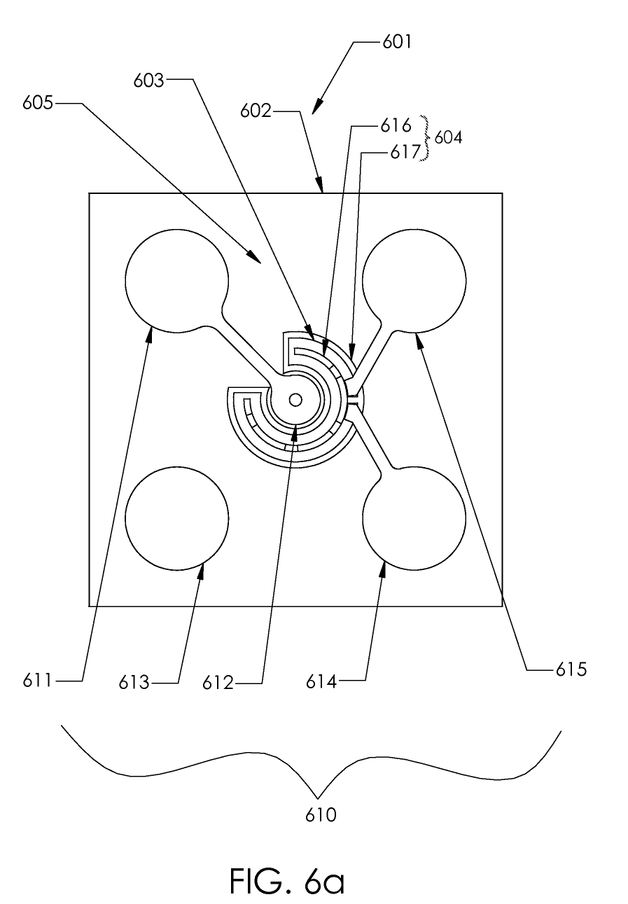

FIG. 7 is a top view of a third example VCSEL 701 which is configured to emit light of up to three different wavelengths simultaneously. For purposes of illustrative clarity, FIG. 7 does not depict insulative regions which may be formed according to the teachings provided above. It will be appreciated, however, with the benefit of the present disclosure, that the VCSEL 701 of FIG. 7 may include insulative regions configured to substantially electrically isolate resistive regions of the VCSEL 701, the insulative regions being formed as described above or using any suitable method.

VCSEL 701 includes a conductive region 702 which includes a top-side contact 703 and a bottom-side contact 704. Top-side contact 703 is electrically connected to top-side header 705. Bottom-side contact 704 is electrically connected to a bottom-side header (not shown) that is electrically connected to three bottom-side electrical connects (not shown). VCSEL 701 further includes three top-side lasing connects 706, 707, and 708, below each of which is a separate corresponding lasing region. The size of the lasing regions generally corresponds to the size of the top-side lasing connects 706, 707, 708. Top-side lasing connect 706 is smaller than top-side lasing connect 707 and top-side lasing connect 708 is larger than top-side lasing connect 707 in the illustrated embodiment. Thus, top-side lasing connects 706, 707, and 708 are each a different size. In other embodiments, two or more of the top-side lasing connects 706, 707, 708 are the same size.

Top-side header 705 is electrically connected to top-side lasing connect 706, first resistive region 711, and second resistive region 712. Optionally, first resistive region 711 and/or second resistive region 712 are disposed proximate to top-side lasing connect 706 or another top-side lasing connect. First resistive region 711 is electrically connected to top-side lasing connect 707. Second resistive region 706 is electrically connected to top-side lasing connect 708.

It is understood that smaller lasing regions generally exhibit larger resistance than larger lasing regions. Thus, for a given amount of current, smaller lasing regions are hotter than larger lasing regions. However, because the smaller lasing regions have larger resistances than larger lasing regions, a resistor may be placed in series with at least one of the larger lasing regions to balance the relative optical power output of each of the lasing regions. Thus, by changing the relative resistances of the first resistive region 711 and the second resistive region 712, a designer can cause each of the lasing regions corresponding to top-side lasing connects 706, 707, 708 to emit light having nominally equal power or can cause each of the lasing regions corresponding to top-side lasing connects 706, 707, 708 to emit light having differing amounts of power, as a particular application requires.

To increase the wavelength separation between the smallest lasing region corresponding to top-side lasing connect 706 and the largest lasing region corresponding to top-side lasing connect 708, second resistive region 712 is disposed proximate to top-side lasing connect 706. Due to the proximity of second resistive region 712 to the smaller lasing region corresponding to top-side lasing connect 706, heat generated by second resistive region 712 increases the temperature of the smaller lasing region corresponding to top-side lasing connect 706, thereby increasing a central wavelength of the light emitted by the smaller lasing region corresponding to top-side lasing connect 706. Specifically, in some embodiments, the heat generated by second resistive region 712 heats the lasing region corresponding to top-side lasing connect 706 from a first temperature to a higher second temperature, the lasing region corresponding to top-side lasing connect 706 emitting light having a first central wavelength when operated at the first temperature and having a higher second central wavelength when operated at the second temperature.

In some embodiments, second resistive region 712 is placed at an appropriate distance from the smaller lasing region corresponding to top-side lasing connect 706 so as to transfer sufficient heat without subjecting the smaller lasing region corresponding to top-side lasing connect 706 or the immediately surrounding area to excessive thermal stress.

### V. Example Operating Environments

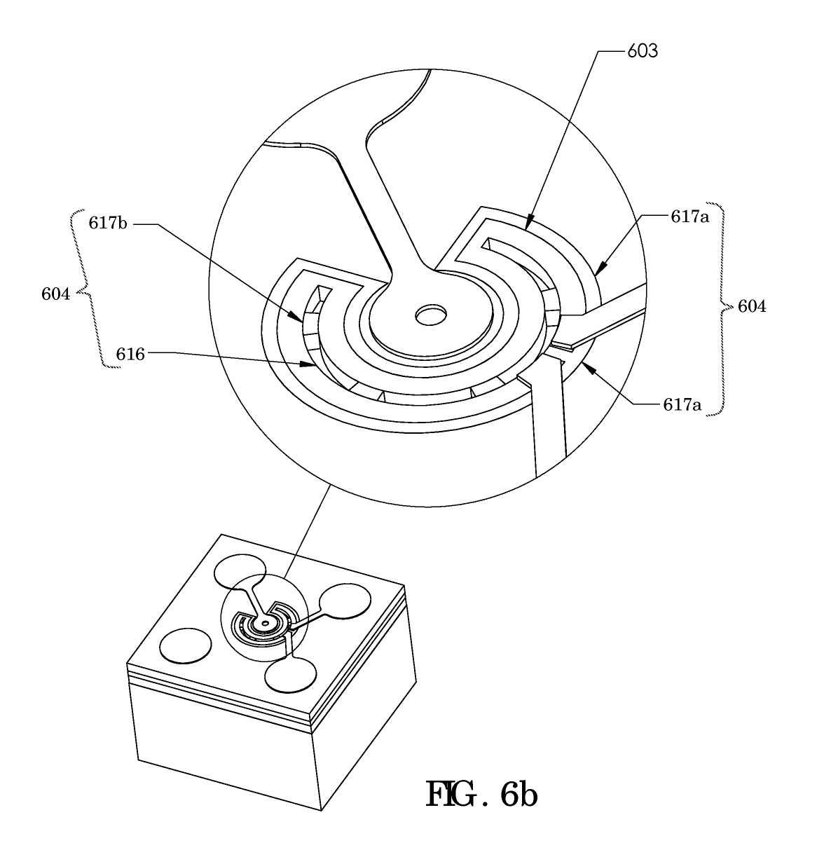

With additional reference to FIG. 8, a first example operating environment is disclosed in which any one of the VCSELs 101, 601, 701 described above can be implemented. FIG. 8 is an exploded perspective view of an example optoelectronic module 801.

The optoelectronic module 801 can be configured for optical signal transmission and reception at a variety of per-second data rates including, but not limited to, 2 Gbit, 4 Gbit, 8 Gbit, 10 Gbit, 40 Gbit, 100 Gbit or higher. Further, the optoelectronic module 801 can be configured for optical signal transmission and reception at various wavelengths, supporting various communication protocols, and operating at various temperature ranges. In addition, although the example optoelectronic module 801 is configured to be substantially compliant with the SFP MSA, the optoelectronic module 801 can instead be configured to assume a variety of different form factors that are substantially compliant with various transceiver and/or transponder MSAs including, but not limited to, SFF, SFP+, XFP, XPAK, X2, XENPAK, QSFP, CXP, or the like.

In the illustrated embodiment, optoelectronic module 801 includes a housing 802, 803, including a bottom shell 802 and a top shell 803. Optoelectronic module 801 further includes a PCBA 804 having various transmitter and receiver circuitry for conditioning electrical signals, a TOSA 805, and a receiver optical subassembly (“ROSA”) 806. The PCBA 804 has an exposed edge connector 807 for electrically connecting to a host device (not shown). The bottom shell 802 includes a plurality of optical ports 808 configured to receive fiber optic connectors coupled to optical fibers.

The TOSA 805 is electrically connected to the PCBA 804 and includes an optical transmitter such as a VCSEL. The ROSA 806 is also electrically connected to the PCBA 804 and includes an optical receiver such as a PIN photodiode. In operation, an incoming optical data signal (e.g., carried by an optical fiber) travels through one of the optical ports 808 into the ROSA 806 and is received by the optical receiver disposed therein. The optical receiver converts the incoming optical data signal to an electrical data signal. The electrical data signal is passed along conductive traces (not shown) to the receiver circuitry on the PCBA 804. The electrical data signal is refined by the receiver circuitry and then passed via edge connector 807 to a host device (not shown) into which the optoelectronic module is positioned.

Similarly, an outgoing electrical data signal is received into the PCBA 804 from the host device via edge connector 807. Transmitter circuitry on the PCBA 804 refines the electrical data signal before passing it along conductive traces (not shown) to the optical transmitter disposed in the TOSA 805. The optical transmitter converts the electrical data signal into an optical data signal which is emitted through one of the optical ports 808 onto an optical fiber disposed therein.

As already indicated above, the TOSA 805 includes an optical transmitter such as a VCSEL. In some embodiments, the optical transmitter included within TOSA 805 is a VCSEL such as the VCSEL 601 of FIG. 6. Alternately or additionally, the optoelectronic module 801 further includes one or more sensors, each configured to generate a signal indicative of a relevant operating or environmental parameter of optoelectronic module 801. The sensors may be disposed, for instance, inside TOSA 805, ROSA 806, or elsewhere within optoelectronic module 801. Further, the sensors are connected to circuitry included on the PCBA 804. Optionally, the one or more sensors include one or more temperature sensors configured to generate a signal indicative of an internal temperature of the optoelectronic module 801, temperature of the VCSEL 601 lasing region, the ambient temperature of VCSEL 601, or the like.

In some embodiments, the PCBA 804 further includes control circuitry configured to supply current to the resistive region 603 of VCSEL 601 within TOSA 805, thus heating the lasing region of VCSEL 601, in response to an indication from the one or more temperature sensors. For instance, the circuitry on PCBA 804 may supply more electrical current to resistive region 603 when the one or more temperature sensors indicate a relatively lower temperature than when the one or more temperature sensors indicate a relatively higher temperature. By controlling the electrical current supplied to the resistive region 603 of VCSEL 601 within TOSA 805, the optoelectronic module 801 maintains a consistent operating temperature at the lasing region of VCSEL 601. When the relevant parameter (e.g., temperature) measured by the one or more temperature sensors is substantially coupled to the heat produced by the resistive region 603 of VCSEL 601, the circuitry on the PCBA 804 can be configured to provide closed-loop control of the current provided to the resistive region 603 of VCSEL 601.

Alternately or additionally, the circuitry on PCBA 804 is configured to provide more or less current to the resistive region 603 of VCSEL 601 in response to parameters other than temperature. For instance, the circuitry on PCBA 804 may adjust the current supplied to the resistive region 603 of VCSEL 601 based on the wavelength of light emitted by the VCSEL 601.

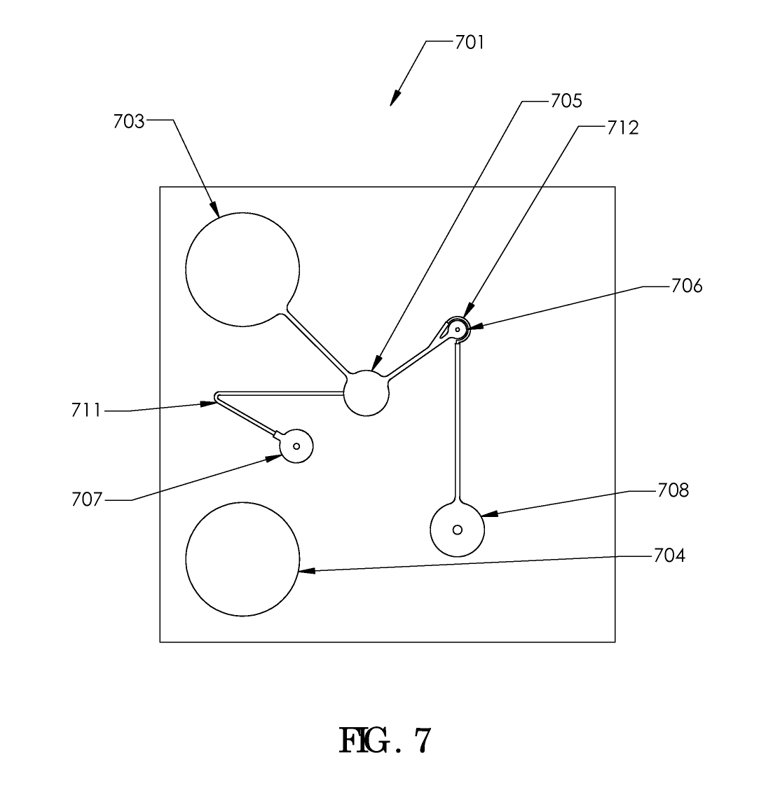

With additional reference to FIG. 9, a second example operating environment is disclosed in which any one of the VCSELs 101, 601, 701 described above can be implemented. Specifically, FIG. 9 illustrates a gas-detection device 901 (“device 901”) in simplified form. Device 901 is configured to detect the presence of various gas molecules according to their light absorption characteristics. It is understood that particular gases absorb more light at certain wavelengths than at other wavelengths such that different types of gasses absorb light of different wavelengths.

In the illustrated embodiment, device 901 includes an optical emitter 902, optical detector 903, control circuitry 904, and chamber 907. Optical emitter 902 is configured to emit a light beam 905 which passes through at least a portion of chamber 907 and is received by optical detector 903. Optical detector 903 generates an electrical signal indicative of the power or intensity of the light beam 905 received by optical detector 903, which electrical signal is provided to control circuitry 904.

During operation, a gas sample is placed in chamber 907. Gas molecules of the gas sample that pass into the light beam absorb some of the light beam 905 if the wavelength of the light beam 905 falls within a certain wavelength range referred to as the “absorption band” of the gas sample. Such absorption diminishes the power of the light beam 905 received by optical detector 903 compared to the power of the light beam 905 before traveling through the chamber 907, thus allowing device 901 to detect gases within the chamber 907.

The optical emitter 902 includes VCSEL 601 which emits light beam 905 having a central wavelength. In this and other examples, control circuitry 904 is configured to provide a current profile to the resistive region 603 of VCSEL 601, thereby causing VCSEL 601 to emit a light beam 905 having a central wavelength that varies in time across a wavelength range. For instance, control circuitry 904 may be set to provide a current profile to the resistive region 603 such that VCSEL 601 emits a light beam 905 having a monotonically increasing central wavelength profile. In some embodiments, the wavelength profile includes a central wavelength of the absorption band of the gas sample in the chamber 907, e.g., the wavelength at which the gas sample absorbs the greatest percentage of light.

Alternately or additionally, the control circuitry 904 is configured to compare the electrical signal produced when the light beam 905 has a relatively high absorption wavelength to the electrical signal produced when the light beam 905 has a relatively lower absorption wavelength, to thereby determine the relative presence or concentration of a particular gas within the chamber 907. For instance, in some cases, the control circuitry 904 is configured to compare the detector signals produced at the wavelengths corresponding to maximum and minimum absorption of the light beam 905. It is understood that one or more of the maximum absorption wavelength, minimum absorption wavelength, and the relative or absolute amounts of absorption at the maximum and/or minimum absorption wavelengths can be used to identify the gas sample within the chamber 902.

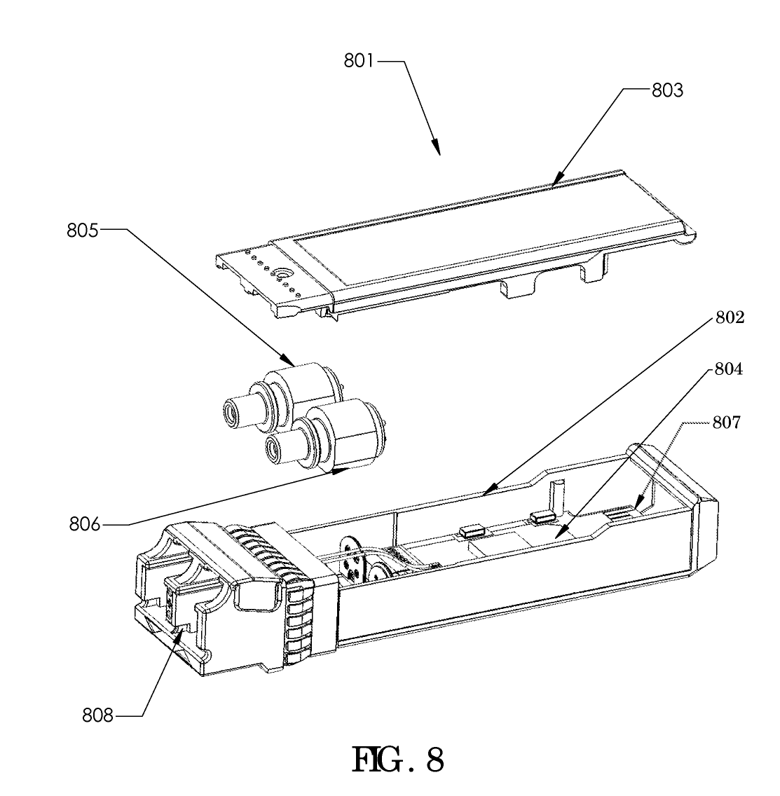

With additional reference to FIG. 10, a third example operating environment is disclosed in which any one of the VCSELs 101, 601, 701 can be implemented. Specifically, FIG. 10 illustrates an example atomic clock 1001. Atomic clock 1001 includes a VCSEL 601, wavelength detector 1003, and control circuitry 1004. In some cases, operation of atomic clock 1001 depends on precise control of the wavelength of light emitted by VCSEL 601. As such, wavelength detector 1003 is configured to provide to control circuitry 1004 an electrical signal indicative of the wavelength of the light emitted from VCSEL 601. Further, control circuitry 1004 is configured to provide current to the resistive region 603 of VCSEL 601 in response to the wavelength indication from wavelength detector 1003. In some cases, control circuitry 1004 includes a controller that provides closed-loop feedback control of the wavelength of light emitted by VCSEL 601 by adjusting the current passing through the resistive region 603 of VCSEL 601.

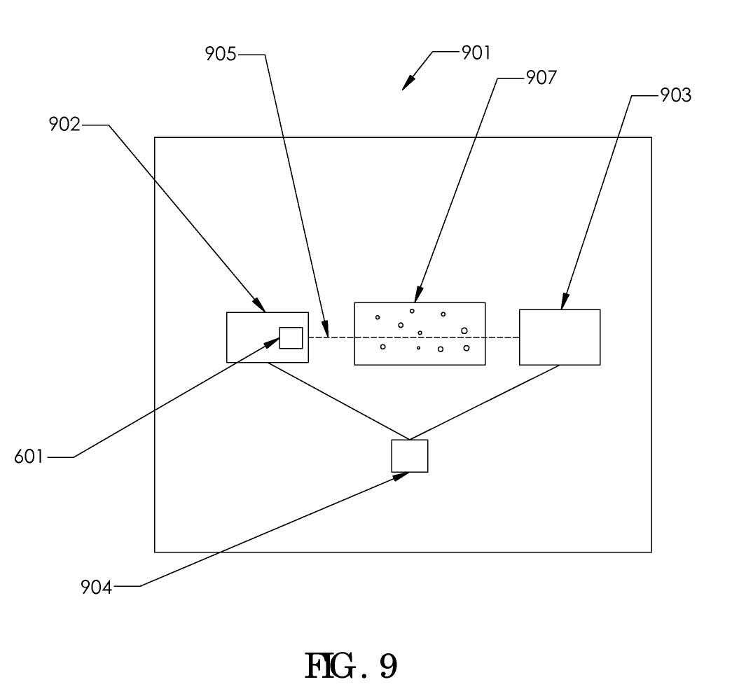

FIG. 11 is a schematic of an example control system 1101 such as may be implemented in the control circuitry 1004 of FIG. 10. Control system 1101 is configured to control the current provided to the resistive region 603 of VCSEL 601. Control system 1101 includes controller 1103, a plant 1102, and a sensor 1104. Plant 1102 includes VCSEL 601. A feedback signal 1111 and input signal 1112 are received at summing junction 1113. The input signal 1112 indicates a desired wavelength or a desired intensity of the light emitted by VCSEL 601. The feedback signal 1111 indicates the actual wavelength or intensity of the light emitted by the VCSEL 601.

Summing junction 1113 combines input signal 1112 with a feedback signal 1111 to create an error signal 1114 indicative of the difference between the desired wavelength or intensity of the light emitted by VCSEL 601 and the actual wavelength or intensity. The error signal 1114 is received by controller 1103. In response to the error signal 1103, controller 1103 provides a control signal 1115 to plant 1102. The control signal 1115 is a current profile in some embodiments.

The control signal 1115 is received by plant 1102 and VCSEL 601. The control signal 1115 increases or decreases the current supplied to resistive region 603, which increases or decreases the amount of heat generated by resistive region 603, thereby resulting in a corresponding adjustment in the wavelength and/or intensity of the light emitted by the VCSEL 601.

A portion of the light emitted by the VCSEL 601, referred to herein as “optical feedback signal 1110,” is received at sensor 1104. The sensor 1104 generates an electrical signal indicative of the wavelength and/or intensity of the optical feedback signal 1110, corresponding to the wavelength and/or intensity of the light emitted by the VCSEL 601, which electrical signal is provided to the summing junction 1113 as feedback signal 1111. In some embodiments, the feedback signal 1111 is an electrical signal proportional to the wavelength and/or intensity of optical feedback signal 1110. Accordingly, control system 1101 provides a means to control the current provided to resistive region 603 of VCSEL 601 based on the wavelength of light emitted by VCSEL 601, the temperature of VCSEL 601, ambient or other temperatures, the intensity of light emitted by VCSEL 601, the power of light emitted by VCSEL 601, or any combination of the above.

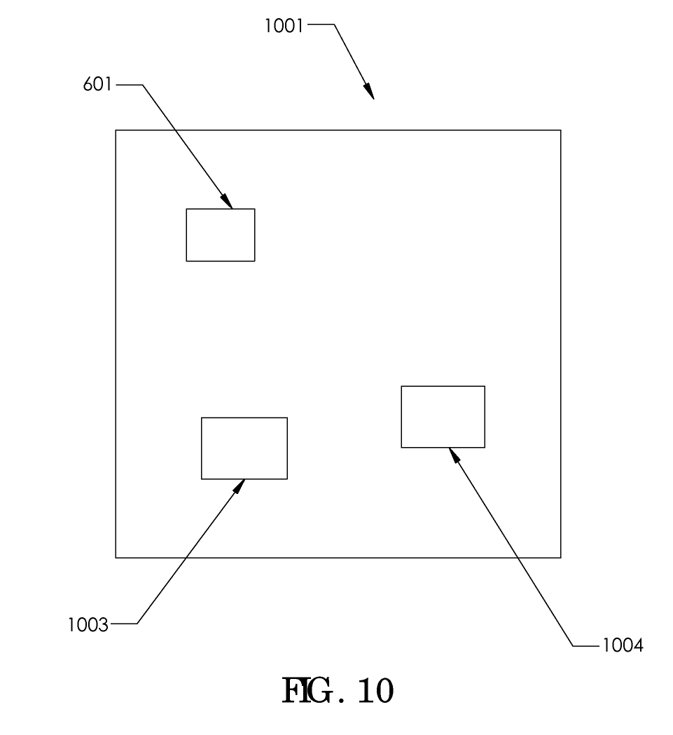

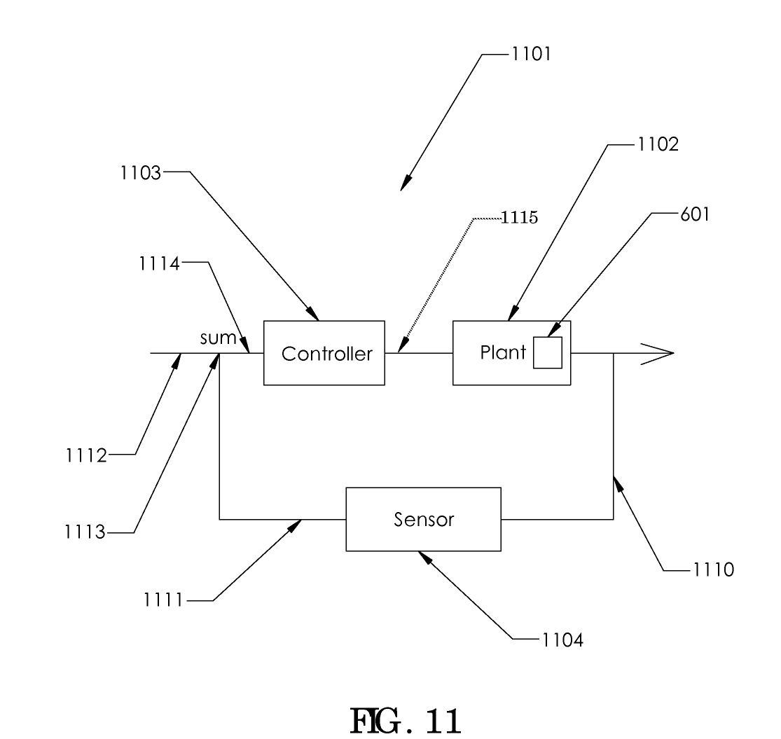

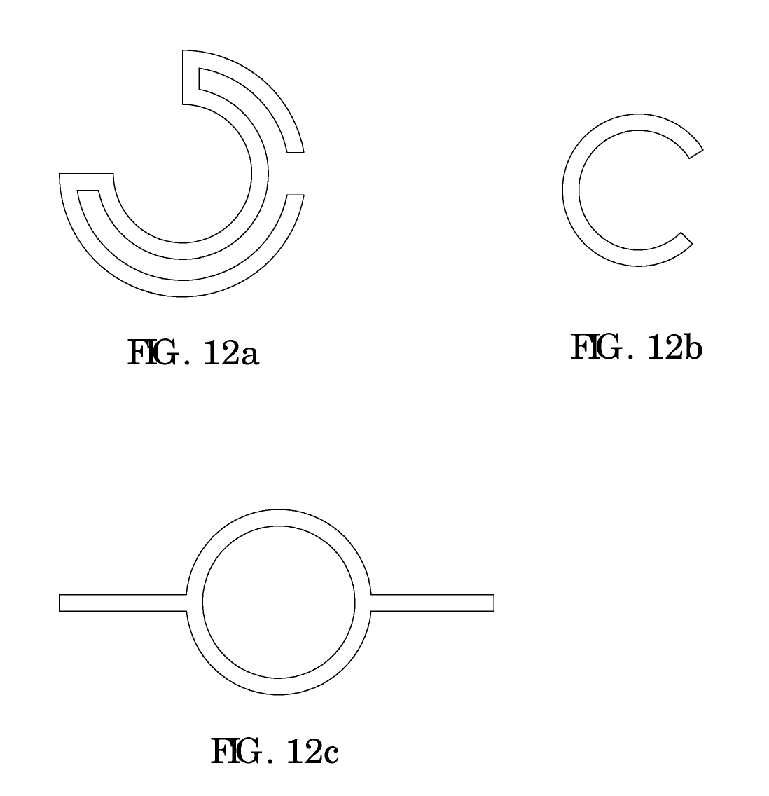

With additional reference to FIGS. 12a-12c, various resistive regions are disclosed that can be implemented in one or more of the VCSELs 101, 601, 701 of FIGS. 1 and 6a-7. For instance, FIG. 12a illustrates a double wrap configuration corresponding to the resistive region 603 of FIGS. 6a-6b. FIG. 12b illustrates a single wrap configuration. Either of the configurations of FIGS. 12a and 12b can be extended to largely surround the VCSEL lasing region, providing symmetric heating, or contracted to a tiny portion or portions of the surrounding region, providing asymmetric heating, as the application might require.

FIG. 12c illustrates a split wrap configuration in which current flows around the VCSEL lasing region in both directions. These and other shapes may be implemented in VCSELs based on the individual requirements of the particular implementation and the design considerations taught herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A vertical cavity surface emitting laser (“VCSEL”) comprising:
a plurality of semiconductor layers, including:
a lower mirror;
an active region disposed over the lower mirror, the active region comprising a first lasing region; and
an upper mirror disposed over the active region;
an insulative region integrally formed in the plurality of semiconductor layers;
a resistive region integrally formed in the plurality of semiconductor layers; and
a remainder region comprising the plurality of semiconductor layers except for the insulative region and the resistive region integrally formed in the plurality of semiconductor layers, the insulative region being disposed between the resistive region and the remainder region.

2. The VCSEL of claim 1, wherein the insulative region is configured to substantially electrically isolate the resistive region from the remainder region.

3. The VCSEL of claim 1, wherein the resistive region is disposed sufficiently close to the first lasing region that a substantial amount of heat generated by the resistive region is transferred to the first lasing region when a nondestructive heating current is passed through the resistive region.

4. The VCSEL of claim 3, wherein the VCSEL is configured to allow substantially independent control of current through the resistive region and operating current through the first lasing region.

5. The VCSEL of claim 4, wherein the nondestructive heating current is less than five times the operating current of the first lasing region.

6. The VCSEL of claim 1, wherein the resistive region and the first lasing region are electrically connected and are configured to collectively present a predetermined input impedance to outside driver circuitry.

7. The VCSEL of claim 6, wherein the resistive region is disposed a sufficient distance from the first lasing region to substantially prevent heat generated by the resistive region from raising the temperature of the lasing region when an operational current is provided to the VCSEL.

8. The VCSEL of claim 7, wherein the VCSEL has a major lateral dimension and the distance of the resistive region from the first lasing region is at least one quarter of the major lateral dimension.

9. The VCSEL of claim 1, further comprising a second lasing region, the second lasing region being smaller than the first lasing region, wherein the resistive region is electrically connected in series with the first lasing region.

10. The VCSEL of claim 9, wherein the resistive region is configured to heat the second lasing region from a first temperature to a second temperature higher than the first temperature, the second lasing region emitting light having a first central wavelength when operated at the first temperature that is smaller than a second central wavelength of light emitted by the second lasing region when operated at the second temperature.

11. The VCSEL of claim 1, wherein the insulative region comprises an insulating base disposed beneath the resistive region.

12. The VCSEL of claim 11, wherein the insulating base comprises an oxidized region formed in an oxidizable layer of at least one of the semiconductor layers.

13. The VCSEL of claim 12, wherein the insulating region further comprises an insulating lateral region including one or more etched regions.

14. The VCSEL of claim 13, wherein the one or more etched regions are configured to allow an oxidant to reach a portion of the oxidizable layer during a manufacturing process to form the oxidized region of the insulating base.

15. The VCSEL of claim 14, wherein the insulating lateral region further comprises one or more ion implant regions.

16. The VCSEL of claim 15, wherein the resistive region has a double wrap configuration.

17. The VCSEL of claim 15, further comprising a conductive region connected to the resistive region, the conductive region not crossing any of the one or more etched regions.

18. A optoelectronic module comprising:
a housing including a top shell and a bottom shell;
a printed circuit board assembly at least partially enclosed within the housing, the printed circuit board assembly including control circuitry;
a transmitter optical subassembly electrically connected to the printed circuit board assembly, the transmitter optical subassembly including a vertical cavity surface emitting laser (“VCSEL”) comprising:
a plurality of semiconductor layers, including:
a lower mirror;
an active region disposed over the lower mirror, the active region comprising a lasing region; and
an upper mirror disposed over the active region;
an insulative region integrally formed in the plurality of semiconductor layers;
a resistive region integrally formed in the plurality of semiconductor layers, disposed proximate the lasing region and electrically connected to the control circuitry; and
a remainder region comprising all of the plurality of semiconductor layers except for the insulative region and the resistive region integrally formed in the plurality of semiconductor layers, the insulative region being configured to substantially electrically isolate the resistive region from the remainder region; and
a temperature sensor electrically connected to the control circuitry, wherein the temperature sensor is configured to generate an electrical signal indicative of a temperature and the control circuitry is configured to adjust an amount of current supplied to the resistive region of the VCSEL in response to the electrical signal.

19. An atomic clock comprising:
control circuitry;
a vertical cavity surface emitting laser (“VCSEL”) electrically connected to the control circuitry, the VCSEL comprising:
a plurality of semiconductor layers, including:
a substrate;
a lower mirror disposed over the substrate;
an active region disposed over the lower mirror, the active region comprising a lasing region; and
an upper mirror disposed over the active region;
an insulative region integrally formed in the plurality of semiconductor layers;
a resistive region integrally formed in the plurality of semiconductor layers, disposed proximate the lasing region and electrically connected to the control circuitry; and
a remainder region comprising all of the plurality of semiconductor layers except for the insulative region and the resistive region, the insulative region being configured to substantially electrically isolate the resistive region from the remainder region; and
a wavelength sensor electrically connected to the control circuitry, the wavelength sensor configured to generate an electrical signal indicative of a wavelength of light emitted by the VCSEL to the control circuitry, the control circuitry being configured to adjust an amount of current provided to the resistive region of the VCSEL in response to the electrical signal.

20. A gas detection device comprising:
a vertical cavity surface emitting laser (“VCSEL”) configured to emit electromagnetic radiation having a central wavelength, the VCSEL comprising:
a plurality of semiconductor layers, including:
a substrate;
a first mirror disposed over the substrate;
an active region disposed over the first mirror, the active region comprising a lasing region; and
a second mirror disposed over the active region;
an insulative region integrally formed in the plurality of semiconductor layers;
a resistive region integrally formed in the plurality of semiconductor layers and disposed proximate the lasing region; and
a remainder region comprising all of the plurality of semiconductor layers except for the insulative region and the resistive region, the insulative region being configured to substantially electrically isolate the resistive region from the remainder region; and
an optical detector disposed in an optical path of the VCSEL;
a gas chamber disposed in the optical path of the VCSEL between the VCSEL and the optical detector;
control circuitry electrically connected to the resistive region of the VCSEL and to the optical detector, the control circuitry configured to vary the central wavelength of the electromagnetic radiation emitted by the VCSEL between a first wavelength and a second wavelength.

21. A method of creating a vertical cavity surface emitting laser (“VCSEL”), the method comprising:
forming a plurality of semiconductor layers including a substrate, a lower mirror and an active region;
forming an upper mirror over the plurality of semiconductor layers, the upper mirror including at least a first layer and a second layer, including:
depositing the first layer above the active region, the first layer having a lower surface and an upper surface and comprising an oxidizable material; and
depositing the second layer over the first layer, the second layer having an upper surface;
forming an etched region in the second layer, the etched region extending from the upper surface of the second layer to a depth that at least partially penetrates the upper surface of the first layer, the etched region being included in an insulative region configured to substantially electrically insulate a resistive region integrally formed in the upper mirror; and
exposing at least the first layer and second layer to an oxidant, wherein the oxidant oxidizes at least a portion of the first layer to form an oxidized region in the first layer, the oxidized region being included in the insulative region and being disposed beneath the resistive region.

22. The method of claim 21, further comprising forming at least a portion of a laser aperture in the upper mirror while simultaneously forming the etched region in the second layer during a single etching process.

23. The method of claim 21, further comprising forming at least a portion of a laser aperture in the upper mirror while simultaneously exposing at least the first and second layers to the oxidant during a single oxidizing process.

24. The method of claim 21, further comprising implanting at least a portion of the upper mirror with ions to form an ion implant region at least in the second layer, the ion implant region being included in the insulative region.

25. The method of claim 24, wherein the plurality of semiconductor layers and the upper mirror are part of a wafer, the method further comprising electrically isolating at least one VCSEL in the wafer while simultaneously implanting the at least a portion of the upper mirror with ions during a single ion implantation process.
